(19) United States
(12) Patent Application Publication
(10) Pub. No.: US 2010/0270582 A1
(43) Pub. Date: Oct. 28, 2010

(54) Coated light-emitting diode

(75) Inventors: Robert J. Nolan, Salisbury, NC (US); Jeffery D. Harman, SR., Salisbury, NC (US)

Correspondence Address: K&L Gates LLP, 214 N. TRYON STREET, HEARST TOWER, 47TH FLOOR, CHARLOTTE, NC, 28202, US

(73) Assignee: Shat-R-Shiel, Inc., Salisbury, NC (US)

(21) Appl. No.: 12/799,230

(22) Filed: Apr. 21, 2010

Related U.S. Application Data
(60) Provisional application No. 61/214,323, filed on Apr. 22, 2009.

(51) Int. Cl. H01L 33/44; H01L 33/52

(52) U.S. Cl. 257/100; 438/26; 257/E33.06

(57) ABSTRACT

The present invention relates to a coated light-emitting diode and the method for making the coated light-emitting diode.

### CROSS-REFERENCE TO RELATED APPLICATIONS

This application claims the benefit of U.S. provisional patent application 61/214, 323, filed Apr. 22, 2009, herein incorporated by reference.

### FIELD OF THE INVENTION

The present invention relates to light-emitting diodes.

### BACKGROUND OF THE INVENTION

A light-emitting diode, also referred to as a LED, is an electronic light source. LEDs have many known advantages over traditional light sources including smaller size, longer lifetime, lower energy consumption, and higher efficiency as measured by its light output per unit power input. The average length of life of a typical LED is estimated to be about 100,000 hours. In order to protect the circuitry and electronic components of a LED for such a duration, exposure to outside forces should be a critical consideration. However, until now there has not been a solution that effectively addresses or solves the problems associated with a LED's exposure to environmental factors such as moisture yet still provides for the known advantages and performance characteristics associated with a LED.

### SUMMARY OF THE INVENTION

The present invention relates to a coated light-emitting diode and the method for making the coated light-emitting diode.

The method of making a coated light-emitting diode in accordance with the present invention comprises providing a light-emitting diode having a surface, and spray coating the surface of the light-emitting diode with a liquid coating composition. In a preferred aspect of the present invention, the liquid coating composition comprises an acrylated urethane.

The coated light-emitting diode in accordance with the present invention comprises a sprayed-on coated surface. In accordance with the present invention the coating is sprayed as a liquid. Preferably, the coated LED is coated with an acrylated urethane composition.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### DETAILED DESCRIPTION OF THE INVENTION

The following detailed description of the embodiment(s) is merely exemplary in nature and is in no way intended to limit the invention, its application, or uses.

The present invention relates to a coated light-emitting diode and the method for making the coated LED. The coated LED of the present invention provides a solution to the problems associated with moisture management while minimizing yellowing and loss of lumen output of the LED.

In accordance with the present invention, a coating is applied to the LED to act as a protective barrier layer to the LED. As a barrier layer, the coating mitigates or prevents moisture and, hence, reduces or eliminates degradation of the LED due to moisture or other degrading elements. The coating after having been applied to the LED forms a clear or transparent film that minimizes yellowing and the loss of lumen output generated by the LED.

The method of the present invention is suitable for use with numerous types, sizes, and shapes of LEDs. There are any number of known types and sizes of LEDs that are commercially available to one of ordinary skill in the art and that could be readily used in accordance with the method of the present invention.

The method of the present invention comprises providing an LED having an exposed surface to be coated. There are numerous commercial suppliers of LEDs. Examples of such commercial suppliers are Seoul Semiconductor, Cree, Inc., Lumileds and Osram Sylvania. A LED suitable for use in the present invention is a white, colored, or multi-colored LED. The particular LED selected often depends upon the desired end-use application. However, one of ordinary skill in the art would know which LEDs are suitable for a given end-use application. The method of the present invention is particularly suitable for any outdoor end-use application or any non-conditioned environment. For example, outdoor signage and street lights are non-limiting examples of potential end-use applications for the coated LED of the present invention.

The method of the present invention comprises coating an exposed surface or a portion of an exposed surface of a LED with a coating composition. The coating acts as a barrier layer and conforms to the shape of the LED. Based upon the spraying technology discussed herein, it is not necessary to mask the electrodes (leads). The spraying technology has computer programmable capabilities that allow the coating to selectively move around the leads. Prior to coating the LED, however, it is still possible for the LED to be prepared by masking the electrodes (leads), such that when the LED is wired to a light there is a clean lead at which to attach the wiring.

The coating composition comprises an acrylated urethane composition. The coating composition is in a form of a liquid.

An acrylated urethane composition suitable for use in the present invention comprises hydroxybutyl acrylate, tetrahydrofufuryl methacrylate, trimethylol propane triacrylate, a photoinitiator, and acrylic acid. Preferably, the acrylated urethane comprises from about 25 to 50 weight percent (wt %) hydroxybutyl acrylate, from about 25 to 50 wt % tetrahydrofufuryl methacrylate, from about 10 to 15 wt % trimethylol propane triacrylate, from about 1 to 5 wt % photoinitiator, and from about 1 to 5 wt % acrylic acid. Such a urethane composition is commercially available as LIGHT-CAP™ 9624 from DYMAX Corporation and may be available from other acrylated urethane suppliers.

In the method of the present invention, the coating composition is applied by spraying the liquid coating composition onto the exposed surface or a portion of an exposed surface of the LED to coat the LED. The LED is preferably sprayed at ambient conditions. The LED may be sprayed in a spray booth.

The liquid coating composition is preferably sprayed with an air-assisted airless spray system or a bead and air swirl system. A bead and air swirl system applies the coating as a bead and uses air to create a swirl pattern. The latter system is desirable because of its improvement in transfer efficiency and because such a system provides good coverage with little bounce back of the liquid spray. The coating can be sprayed at ambient conditions. The LED shape is programmed into the spray system with the exact area to coat and the area to leave uncoated. Since spray time is based upon the size and shape of the LED, spray times vary up to about twenty seconds. The thickness of the coating is typically in a range of 5 to 8 mils. Examples of commercially available spray systems include, but are not limited to, Asymtek of Nordson Corporation or systems available from PVA.

Subsequent to being spray coated, the coated LED is cured. Curing typically occurs in a curing oven. Ultraviolet (UV) light waves may be used to cure the coated LED. Ultraviolet lamps or lights are preferably employed for this purpose. Examples of suitable UV lamps are commercially available from Fusion UV Systems, Inc. Preferably, the UV lamps provide approximately 2500 mW/cm² of power. The UV lamps provide a more consistent light output over the life of the lamp, thus requiring less adjustment to the production speed due to the change in the light wavelength. As the LED exits the curing oven, the LED is cooled in ambient conditions. The masking on the electrodes (leads) is removed.

The production rate of coated LEDs varies depending upon the size and shape of the LED as well as its end-use application. For example, the production rate varies depending upon whether there is linear or down lighting. Based upon the end-use application, typical production speeds may vary between 90 to 150 parts per hour.

As indicated herein, an acrylated urethane coating composition spray coated on the LED provides a transparent moisture management system that lasts the length of life for the LED yet minimized yellowing and loss of lumen output. The liquid spray coating method is particularly desirable as compared to other coating methods that might otherwise be available. For example, it was determined from experimentation that it was difficult to get an even coating as well as a smooth coating with a powder spray. For example, the powder coatings cured with a convection oven were grainy and the LED detached from its base due to the curing temperature, thus creating aesthetic and performance failures.

It will therefore be readily understood by those persons skilled in the art that the present invention is susceptible of broad utility and application. Many embodiments and adaptations of the present invention other than those herein described, as well as many variations, modifications and equivalent arrangements, will be apparent from or reasonably suggested by the present invention and the foregoing description thereof, without departing from the substance or scope of the present invention. Accordingly, while the present invention has been described herein in detail in relation to its preferred embodiment, it is to be understood that this disclosure is only illustrative and exemplary of the present invention and is made merely for purposes of providing a full and enabling disclosure of the invention. The foregoing disclosure is not intended or to be construed to limit the present invention or otherwise to exclude any such other embodiments, adaptations, variations, modifications and equivalent arrangements.

What is claimed is:

1. A method of making a coated light-emitting diode, the method comprising:
providing a light-emitting diode having a surface, and
spray coating the surface of the light-emitting diode with a liquid coating composition.

2. The method according to claim 1, wherein the coating is sprayed on a portion of the surface of the light-emitting diode or the entire surface of the light-emitting diode.

3. The method according to claim 1, wherein the spray coating conforms to the surface of the light-emitting diode.

4. The method according to claim 1, wherein the coating composition comprises an acrylated urethane.

5. The method according to claim 4, wherein the acrylated urethane composition comprises from about 25 to 50 weight percent (wt %) hydroxybutyl acrylate, from about 25 to 50 wt % tetrahydrofufuryl methacrylate, from about 10 to 15 wt % trimethylol propane triacrylate, from about 1 to 5 wt % photoinitiator, and from about 1 to 5 wt % acrylic acid.

6. The method according to claim 1, further comprising curing the coated LED.

7. The method according to claim 6, wherein the coated LED is cured with ultraviolet light.

8. The method according to claim 7, wherein curing is in a curing oven.

9. The method according to claim 1, wherein the acrylated urethane coating is transparent.

10. The method according to claim 1, further comprising spraying the coating with an air-assisted airless system or a bead and air swirl system.

11. A method of making a coated light-emitting diode, the method comprising:
providing a light-emitting diode having a surface, and
spray coating the surface of the light-emitting diode with a liquid coating composition comprising acrylated urethane.

12. A light-emitting diode having a coated surface, wherein the coating of the coated LED comprises an acrylated urethane composition.

13. The light-emitting diode according to claim 12, wherein the coated LED has a sprayed-on coating on the surface of the light-emitting diode.

14. The light-emitting diode according to claim 12, wherein the acrylated urethane composition comprises from about 25 to 50 weight percent (wt %) hydroxybutyl acrylate, from about 25 to 50 wt % tetrahydrofufuryl methacrylate, from about 10 to 15 wt % trimethylol propane triacrylate, from about 1 to 5 wt % photoinitiator, and from about 1 to 5 wt % acrylic acid.

15. The light-emitting diode according to claim 13, wherein the sprayed-on coating is cured.

16. The light-emitting diode according to claim 15, wherein the coated light-emitting diode is cured with ultraviolet light.

17. The light-emitting diode according to claim 16, wherein the coated light-emitting diode is cured in a curing oven.

18. The light-emitting diode according to claim 12, wherein the acrylated urethane coating is transparent.

19. The light-emitting diode according to claim 12, wherein the acrylated urethane coating conforms to the surface of the light-emitting diode.

20. The light-emitting diode according to claim 12, wherein the coating is sprayed on a portion of the surface or the entire surface of the light-emitting diode.
